(19) United States
(12) Patent Application Publication
(10) Pub. No.: US 2024/0194581 A1
(43) Pub. Date: Jun. 13, 2024

(54) POWER MODULE AND MANUFACTURING METHOD THEREFOR

(71) Applicant: AMOSENSE CO., LTD., Cheonan-si, Chungcheongnam-do (KR)

(72) Inventor: Jihyung LEE, Cheonan-si (KR)

(73) Assignee: AMOSENSE CO., LTD., Cheonan-si, Chungcheongnam-do (KR)

(21) Appl. No.: 18/287,012

(22) PCT Filed: Apr. 7, 2022
(86) PCT No.: PCT/KR2022/005040

§ 371 Date: Oct. 15, 2023

(30) Foreign Application Priority Data
Apr. 14, 2021 (KR) 10-2021-0048148

(51) Int. Cl. H01L 23/498; H01L 23/00; H01L 23/15; H01L 23/31; H01L 23/373; H01L 23/492

(52) U.S. Cl. CPC H01L 23/49844; H01L 23/15; H01L 23/3142; H01L 23/3735; H01L 23/4924; H01L 24/32; H01L 24/83; H01L 2224/32225; H01L 2224/83801; H01L 2924/351

(57) ABSTRACT

The present invention relates to a power module and a manufacturing method therefor, the power module using a conductive spacer to electrically connect an electrode of a semiconductor chip and an electrode pattern of a ceramic substrate without a wire, thereby converting rated voltage and current while removing electrical risk elements, which can be generated during wire bonding, and increasing reliability and efficiency when used with high power.

### TECHNICAL FIELD

The present disclosure relates to a power module and a method for manufacturing the same, and more particularly, to a power module and a method for manufacturing the same, in which electrodes of a semiconductor chip and an electrode pattern of a ceramic substrate are electrically connected without a wire.

### BACKGROUND ART

A power module is a semiconductor module optimized for power conversion or control through modularization of a semiconductor chip onto a package.

The power module has a structure in which a substrate is put on a base plate, and a semiconductor chip is put on the substrate.

The existing power module is so configured that a semiconductor chip is electrically connected to a substrate by wire bonding (Bond-wire) made of gold (Au), copper (Cu), and aluminum (Al) and the substrate is also connected to a PCB by the wire bonding (Bond-wire). That is, the existing power module has a structure in which a power transfer line for an electric signal and power conversion is made by the wire bonding.

However, according to such a wire bonding structure, there is a possibility that a short or disconnection occurs due to electrical energy with high power and high current, and this may cause potential risk factors of an entire vehicle.

### SUMMARY OF INVENTION

### Technical Problem

The present disclosure has been devised to solve the above-described problem, and an object of the present disclosure is to provide a power module, which can exclude high-power and high-current electrical risk factors by electrically connecting electrodes of a semiconductor chip and an electrode pattern of a ceramic substrate to each other without a wire through the medium of a conductive spacer.

### Solution to Problem

In order to achieve the above object, a power module according to an embodiment of the present disclosure may include: a ceramic substrate on which an electrode pattern made of a metal is formed on at least one surface of a ceramic base material; a conductive spacer having a lower surface that is bonded onto the electrode pattern of the ceramic substrate; a semiconductor chip on which electrodes are bonded onto an upper surface of the conductive spacer; and a brazing filler layer configured to braze the electrode pattern of the ceramic substrate and the lower surface of the conductive spacer.

An edge of the conductive spacer may be disposed adjacent to an edge of the electrode pattern.

The conductive spacer may include: a first conductive spacer in the form of an “L” shape, and disposed adjacent to an edge of the “L” shape on the electrode pattern; and a second conductive spacer disposed spaced apart from the first conductive spacer, and having a side surface facing a side surface of the first conductive spacer.

The conductive spacer may have a side surface that is etched to form a curved surface, and an area of the lower surface of the conductive spacer may be formed to be larger than an area of the upper surface of the conductive spacer.

The conductive spacer may be formed of at least one of Cu, Mo, a CuMo alloy, and a CuW alloy.

The brazing filler layer may be made of a material including at least one of Ag, Cu, AgCu, and AgCuTi.

The electrodes of the semiconductor chip may be bonded onto the upper surface of the conductive spacer by a bonding layer including a solder or a silver paste (Ag paste).

A method for manufacturing a power module according to an embodiment of the present disclosure may include: preparing a ceramic substrate by forming an electrode pattern made of a metal on at least one surface of a ceramic base material; preparing a conductive spacer; brazing a lower surface of the conductive spacer onto the electrode pattern of the ceramic substrate; and bonding electrodes of a semiconductor chip onto an upper surface of the conductive spacer.

The preparing of the conductive spacer may prepare the conductive spacer having a side surface formed as a curved surface through etching of the conductive spacer, and an area of the lower surface of the conductive spacer may be formed to be larger than an area of the upper surface of the conductive spacer.

In the preparing of the conductive spacer, the conductive spacer may be formed of at least one of Cu, Mo, a CuMo alloy, and a CuW alloy.

The brazing may include disposing an edge of the conductive spacer adjacent to an edge of the electrode pattern.

The brazing may include: disposing a brazing filler layer having a thickness that is equal to or larger than 5 μm and equal to or smaller than 100 μm on an upper surface of the electrode pattern by any one method of paste application, foil attachment, and P-filler; and brazing the brazing filler layer through melting.

In the disposing of the brazing filler layer, the brazing filler layer may be made of a material including at least one of Ag, Cu, AgCu, and AgCuTi.

The brazing may be performed at a temperature that is equal to or higher than 450° C.

The bonding of the electrodes of the semiconductor chip may bond the electrodes of the semiconductor chip onto the upper surface of the conductive spacer by any one method of soldering and sintering.

### Advantageous Effects of Invention

According to the present disclosure, since the electrodes of the semiconductor chip and the electrode pattern of the ceramic substrate are electrically connected through the conductive spacer without the wire, the rated voltage and current can be converted while removing the electrical risk elements that may occur during wire bonding, and the reliability and efficiency can be heightened when used with the high power.

Further, according to the present disclosure, since the conductive spacer is disposed between the electrode pattern of the ceramic substrate and the electrodes of the semiconductor chip, it is possible to easily adjust the height between the ceramic substrate and the semiconductor chip to correspond to the height of a molding mold during a molding process.

Further, according to the present disclosure, since heat generated from the semiconductor chip is easily transferred to the ceramic substrate through the conductive spacer, the heat dissipation efficiency can be heightened.

Further, according to the present disclosure, since lower surface of the conductive spacer is brazed onto the electrode pattern of the ceramic substrate through the brazing filler layer, and the upper surface of the conductive spacer is brazed onto the electrodes of the semiconductor chip through the bonding layer including the solder or silver paste, the bonding strength is high, and the high-temperature reliability is excellent.

### BRIEF DESCRIPTION OF DRAWINGS

FIG. 1 is a plan view illustrating a ceramic substrate and a conductive spacer in a power module according to an embodiment of the present disclosure.

FIG. 2 is a perspective view illustrating a state where a semiconductor chip is disposed on a conductive spacer in a partial area indicated by “A” of FIG. 1.

FIG. 3 is an enlarged perspective view illustrating a second conductive spacer in a power module according to an embodiment of the present disclosure.

FIG. 4 is a cross-sectional view illustrating the second conductive spacer of FIG. 3.

FIG. 5 is a right side view illustrating a state where electrodes of a semiconductor chip are disposed on a conductive spacer bonded onto a ceramic substrate in a power module according to an embodiment of the present disclosure.

FIG. 6 is a right side view illustrating a state where electrodes of a semiconductor chip are bonded onto a conductive spacer bonded onto a ceramic substrate in a power module according to an embodiment of the present disclosure.

FIG. 7 is a flowchart illustrating a method for manufacturing a power module according to an embodiment of the present disclosure.

### DESCRIPTION OF EMBODIMENTS

Hereinafter, embodiments of the present disclosure will be described in detail with reference to the accompanying drawings. In describing the embodiments, the standards for upper/above or lower/under will be described based on the drawings.

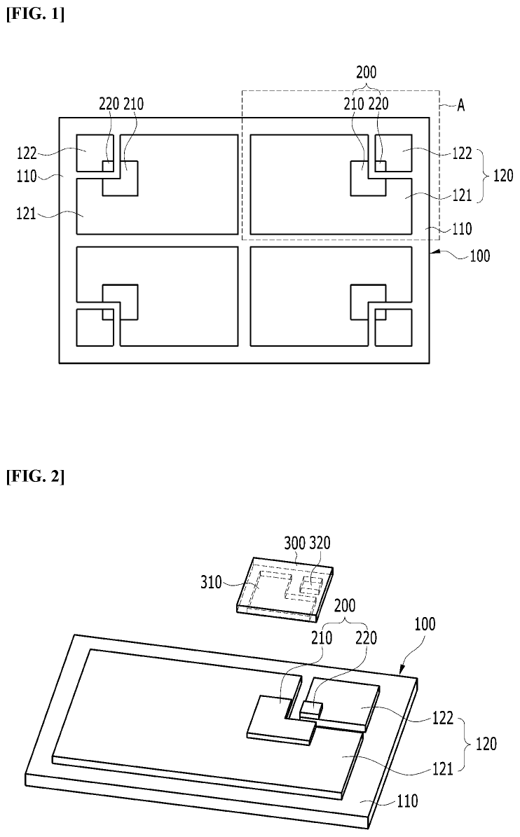

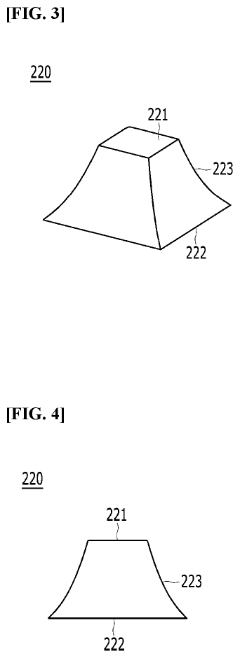

FIG. 1 is a plan view illustrating a ceramic substrate and a conductive spacer in a power module according to an embodiment of the present disclosure, and FIG. 2 is a perspective view illustrating a state where a semiconductor chip is disposed on a conductive spacer in a partial area indicated by “A” of FIG. 1.

As illustrated in FIGS. 1 and 2, a power module 1 according to an embodiment of the present disclosure may be provided with a ceramic substrate 100, a conductive spacer 200, and a semiconductor chip 300, and may be packaged in a case (not illustrated). According to the power module 1 of the present disclosure, unlike a power module in the related art using wire bonding, since the semiconductor chip 300 is bonded onto an upper part of the ceramic substrate 100 through the conductive spacer 200, the wire bonding can be omitted, so that the electrical risk elements of the high power and high current can be excluded, and the heat dissipation performance can be improved.

The ceramic substrate 100 may be any one of an active metal brazing (AMB) substrate, a direct bonded copper (DBC) substrate, and a thick printing copper (TPC) substrate. Here, the ceramic substrate 100 may be provided as a ceramic substrate on which an electrode pattern 120 of a metal layer is formed on at least one surface of a ceramic base material 110 so as to heighten the heat dissipation efficiency against heat that is generated from the semiconductor chip 300.

As an example, the ceramic base material 110 may be any one of alumina (Al₂O₃), AlN, SiN, and Si₃N₄. The metal layer may be formed as an electrode pattern for mounting the semiconductor chip and an electrode pattern for mounting a driving element through brazing of a metal foil onto the ceramic base material 110. For example, the metal layer may be formed as an electrode pattern in an area where the semiconductor chip or a peripheral component is to be mounted. As an example, the metal foil is an aluminum foil or a copper foil. As an example, the metal foil is sintered on the ceramic base plate 110 at 780° ° C. to 1100° C., and is brazed onto the ceramic base material 110. Such a substrate is called an active metal brazing (AMB) substrate. Although the AMB substrate is exemplified in the embodiment, a direct bonding copper (DBC) substrate, a thick printing copper (TPC) substrate, or a direct brazed aluminum (DBA) substrate may be applied. Here, the AMB substrate is best suited for durability and heat dissipation efficiency.

The ceramic substrate 100 may be provided with a plurality of electrode patterns 120 separated from each other by space on the same surface of the ceramic substrate 110. As an example, the plurality of electrode patterns 120 may include a first electrode pattern in the form of an “L” shape, and a second electrode pattern 122 disposed to form a rectangular cross-section together with the first electrode pattern 121. Four groups of the first electrode pattern 121 and the second electrode pattern 122 may be formed on one surface of the ceramic base material 110, but the number and the shape of the electrode pattern 120 may not be limited thereto, and may be changed.

At least one conductive spacer 200 may be provided, and a lower surface of the conductive spacer 200 may be bonded onto the electrode pattern 120 of the ceramic substrate 100. The conductive spacer 200 may be disposed so that an edge thereof is adjacent to an edge of the electrode pattern 120. As an example, the conductive spacer 200 may be provided with a first conductive spacer 210 in the form of an “L” shape, and disposed adjacent to an edge of the “L” shape of the first electrode pattern 121, and a second conductive spacer 220 of a block type.

The second conductive spacer 220 may be disposed adjacent to the edge of the second electrode pattern 122, may be spaced apart from the first conductive spacer 210, and may have a side surface facing a side surface of the first conductive spacer 210. Four groups of the first conductive spacer 210 and the second conductive spacer 220 may be formed to correspond to the number of the first and second electrode patterns 122, but the number thereof is not limited thereto.

The conductive spacer 200 may be provided to electrically connect the ceramic substrate 100 and the semiconductor chip 300 with each other and to adjust the height between the ceramic substrate 100 and the semiconductor chip 300. The conductive spacer 200 may be provided in the form of a small block having a size equal to or larger than 0.5 mm×0.5 mm and a thickness equal to or larger than 0.3 mm.

The power module 1 may be sealed with an epoxy-series molding resin (not illustrated) in order to protect the semiconductor chip 300 from an external environment. The molding resin may be melt under high temperature and high pressure, be injected into a molding mold (not illustrated) in a liquid form, be cured to protect the semiconductor chip 300 and the like from an external environment, such as physical impact, moisture, pollution, and the like, and stably maintain the bonding state of the respective constituent elements. Since the molding mold is used in the molding process, it is necessary to adjust the height between the ceramic substrate 100 and the semiconductor chip 300 to correspond to the height of the molding mold. If the height between the ceramic substrate 100 and the semiconductor chip 300 is not properly adjusted to correspond to the height of the molding mold, a problem may occur in filling epoxy molding compound (EMC) in the molding mold. In case of replacing the equipment, such as the molding mold to correspond to the height between the ceramic substrate 100 and the semiconductor chip 300, a lot of costs occur, and thus it is unfavorable.

Accordingly, according to the power module according to the present disclosure, since the conductive spacer 200 is disposed between the electrode pattern 120 of the ceramic substrate 100 and the electrodes 310 and 320 of the semiconductor chip 300, it is possible to easily adjust the height between the ceramic substrate 100 and the semiconductor chip 300 to correspond to the height of the molding mold. As an example, the height of the molding mold may be 3 mm to 4 mm, and the thickness of the conductive spacer 200 may be equal to or larger than 0.3 mm.

In case of adjusting the height by forming the electrode pattern 120 of the ceramic substrate 100 higher without disposing the conductive spacer 200, it is required to further heighten the entire height of the electrode pattern 120 made of a metal, and this may cause a lot of costs to occur. In contrast, according to the present disclosure, since the conductive spacer 200 is disposed in a portion where the electrodes 310 and 320 of the semiconductor chip 300 are bonded onto the electrode pattern 120 of the ceramic substrate 100, it is much cheaper in cost. Further, since the height between the ceramic substrate 100 and the semiconductor chip 300 can be adjusted easily and variously by the conductive spacer 200 to correspond to the molding mold, the productivity can be improved.

Further, the conductive spacer 200 is a conductor, and may be used to connect circuits. That is, since the electrodes 310 and 320 of the semiconductor chip 300 is bonded onto the upper surface of the conductive spacer 200 in a state where the lower surface of the conductive spacer 200 is brazed onto the electrode pattern 120 of the ceramic substrate 100, it is possible to electrically connect the electrodes 310 and 320 of the semiconductor chip 300 to the electrode pattern 120 of the ceramic substrate 100 without a wire.

As described above, according to the present disclosure, since the wire bonding can be omitted by directing connecting the electrodes 310 and 320 of the semiconductor chip 300 and the electrode pattern 120 of the ceramic substrate 100 to each other by using the conductive spacer 200, the rated voltage and current can be converted while removing the electrical risk elements that may occur during the wire bonding, and the reliability and efficiency can be heightened when used with the high power.

The conductive spacer 200 may be made of at least one of Cu, Al, AlSiC, CuMo, CuW, Cu/CuMo/Cu, Cu/Mo/Cu, and Cu/W/Cu, or a composite material thereof. Preferably, the conductive spacer 200 may be formed of at least one of Cu, Mo, a CuMo alloy, and a CuW alloy having excellent thermal expansion coefficient and thermal conductivity.

As an example, the conductive spacer 200 may have a three-layer structure of Cu/CuMo/Cu. The three-layer structure of Cu/CuMo/Cu may have a high thermal conductivity to be good for heat dissipation, have a low thermal expansion coefficient to be able to stably maintain an interval between the ceramic substrate 100 and the semiconductor chip 300 even at a high temperature, and can minimize flexure occurrence during being brazed onto the electrode pattern 120 of the ceramic substrate 100.

The conductive spacer 200 may be provided in a state where the thermal stress and thermal deformation thereof are pre-removed through the heat treatment. If the thermal stress and the thermal deformation are pre-removed, the thermal stress that is created by the thermal expansion and thermal contraction in the process of brazing the electrode pattern 120 of the ceramic substrate 100 and the conductive spacer 200 onto each other can be relieved, and thus the bonding strength can be improved. Further, since the bonding region is not damaged, the heat transfer effect can be excellent.

At least one semiconductor chip 300 may be provided, and any one of a Si chip, SiC chip, GaN chip, metal oxide semiconductor field effect transistor (MOSFET), insulated gate bipolar transistor (IGBT), junction field effect transistor (JFET), and high electric mobility transistor (HEMT) may be provided.

The first electrode 310 and the second electrode 320 may be provided on one surface of the semiconductor chip 300. The first electrode 310 may be bonded onto the upper surface of the first conductive spacer 210, and the second electrode 320 may be bonded onto the upper surface of the second conductive spacer 220. The first electrode 310 may be a source electrode of the semiconductor chip 300, and the second electrode 320 may be a gate electrode of the semiconductor chip 300. The gate electrode is an electrode for turning on/off the semiconductor chip 300 by using a lower voltage, and the source electrode is an electrode for making a high current come in or go out.

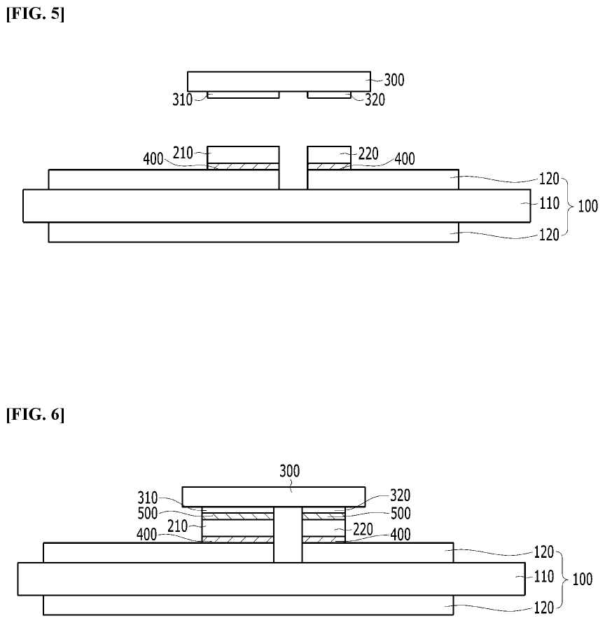

FIG. 3 is an enlarged perspective view illustrating a second conductive spacer in a power module according to an embodiment of the present disclosure, and FIG. 4 is a cross-sectional view illustrating the second conductive spacer of FIG. 3.

As illustrated in FIGS. 3 and 4, an area of a lower surface 222 of the second conductive spacer 220 may be formed to be larger than an area of an upper surface 221 of the second conductive spacer 220. The second conductive spacer 220 may be formed by etching, and a side surface 223 of the second conductive spacer 220 may be etched to form a curved surface. In this case, it is preferable that the upper surface 221 of the second conductive spacer 220 is formed with an area corresponding to the second electrode 320 of the semiconductor chip 300. If the area of the upper surface 221 of the second conductive spacer 220 becomes narrower than the area of the second electrode 320, the bonding may become difficult. As an example, the upper surface 221 of the second conductive spacer 220 may be formed with a size of 0.6 mm×0.6 mm to correspond to the second electrode 320, and the lower surface 222 thereof may be formed with a size of 1.2 mm×1.2 mm. Since as the area of the lower surface 222 becomes narrower, it is not possible to maintain sufficient electrical properties, and there is a possibility of peeling off from the electrode pattern 120 of the ceramic substrate 100, it is preferable to form the lower surface 222 with a larger area than the area of the upper surface 221.

Meanwhile, although not illustrated, the first conductive spacer 210 may be formed by etching in the same manner as the second conductive spacer 220, and through this, the side surface thereof may be etched to form a curved surface, and the lower surface may be formed with a larger area than the area of the upper surface.

As described above, the conductive spacer 200 may be processed with a proper size by etching, and if needed, machining may be further performed.

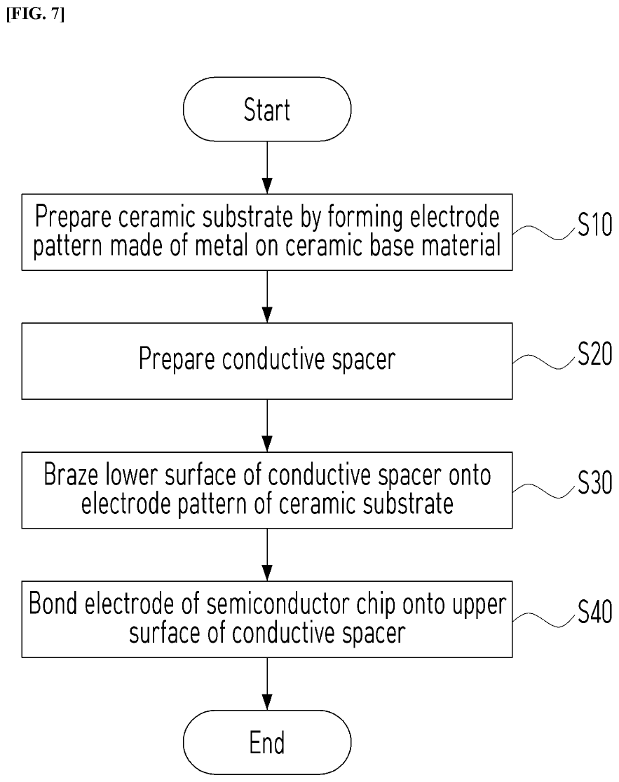

FIG. 5 is a right side view illustrating a state where electrodes of a semiconductor chip are disposed on a conductive spacer bonded onto a ceramic substrate in a power module according to an embodiment of the present disclosure, and FIG. 6 is a right side view illustrating a state where electrodes of a semiconductor chip are bonded onto a conductive spacer bonded onto a ceramic substrate in a power module according to an embodiment of the present disclosure.

As illustrated in FIGS. 5 and 6, the lower surface of the conductive spacer 200 may be brazed onto the electrode pattern 120 of the ceramic substrate 100 through the brazing filler layer 400, and the upper surface thereof may be brazed onto the electrodes 310 and 320 of the semiconductor chip 300 through a bonding layer 500.

The brazing filler layer 400 may braze the electrode pattern 120 of the ceramic substrate 100 and the lower surface of the conductive spacer 200 onto each other, and may be composed of a material including at least one of Ag, Cu, AgCu, and AgCuTi. Here, Ag and Cu have a high thermal conductivity, and thus serve to heighten not only the bonding force but also the heat dissipation efficiency by facilitating the heat transfer between the ceramic substrate 100 and the conductive spacer 200. Further, Ti has a good wettability, and thus may facilitate attachment of Ag and Cu onto the electrode pattern 120 of the ceramic substrate 100.

The brazing filler layer 400 may be formed as a thin film of a multilayer structure. The thin film of the multilayer structure is to heighten the bonding force by making up for the poor performance. As an example, the brazing filler layer 400 may be composed of a two-layer structure including an Ag layer and a Cu layer formed on the Ag layer. Further, the brazing filler layer 400 may be composed of a three-layer structure including a Ti layer, an Ag layer formed on the Ti layer, and a Cu layer formed on the Ag layer. After the brazing filler layer 400 is used for the brazing of the electrode pattern 120 of the ceramic substrate 100 and the conductive spacer 200, the boundary of the multilayer structure may become ambiguous. The brazing may be performed at 450° ° C. or more.

The bonding layer 500 is to bond the electrodes 310 and 320 of the semiconductor chip 300 and the upper surface of the conductive spacer 200 onto each other, and may include a solder or a silver paste (Ag paste). In order to braze all of the upper surface and the lower surface of the conductive spacer 200, it is required to perform the brazing process twice, and thus the flexure may occur on the ceramic substrate 100. Accordingly, it is preferable that the upper surface of the conductive spacer 200 is bonded onto the electrodes 310 and 320 of the semiconductor chip 300 by the bonding layer 500 including the solder or silver paste.

The solder may be composed of the solder paste of SnPb series, SnAg series, SnAgCu series, and Cu series having a high bonding strength and excellent high-temperature reliability. The silver paste has the excellent high-temperature reliability and high thermal conductivity in comparison to the solder. It is preferable that the silver paste includes 90 to 99 weight % of Ag powder and 1 to 10 weight % of binder so as to heighten the thermal conductivity. It is preferable that the Ag powder is composed of nanoparticles. The Ag powder of nanoparticles has a high bonding density and high thermal conductivity due to its large surface area.

As described above, according to the power module 1 according to an embodiment of the present disclosure, it is possible to electrically connect the electrodes 310 and 320 of the semiconductor chip 300 to the electrode pattern 120 of the ceramic substrate 100 without a wire through the conductive spacer 200, and to adjust the height between the ceramic substrate 100 and the semiconductor chip 300 easily and variously to correspond to the molding mold, and thus the productivity can be improved. Further, since the heat generated from the semiconductor chip 300 is transferred to the ceramic substrate 100 through the conductive spacer 200, the heat dissipation efficiency can be heightened. In addition, since the lower surface of the conductive spacer 200 is brazed onto the electrode pattern 120 of the ceramic substrate 100 through the brazing filler layer 400, and the upper surface thereof is bonded onto the electrodes 310 and 320 of the semiconductor chip 300 through the bonding layer 500, the bonding strength is high, and the high-temperature reliability is excellent.

FIG. 7 is a flowchart illustrating a method for manufacturing a power module according to an embodiment of the present disclosure.

As illustrated in FIG. 7, a method for manufacturing a power module according to an embodiment of the present disclosure may include: preparing a ceramic substrate 100 by forming an electrode pattern 120 made of a metal on at least one surface of a ceramic base material 110 (S10); preparing a conductive spacer 200 (S20); brazing a lower surface of the conductive spacer 200 onto the electrode pattern 120 of the ceramic substrate 100 (S30); and bonding electrodes 310 and 320 of a semiconductor chip 300 onto an upper surface of the conductive spacer 200.

In the preparing of the ceramic substrate 100 (S10), the ceramic substrate 100 may be any one of an active metal brazing (AMB) substrate, a direct bonded copper (DBC) substrate, and a thick printing copper (TPC) substrate. Here, on the ceramic substrate 100, an electrode pattern 120 of a metal layer may be formed on at least one surface of a ceramic base material 110 so as to heighten the heat dissipation efficiency against heat that is generated from the semiconductor chip 300. Here, the ceramic base material 110 may be any one of alumina (Al₂O₃), AlN, SiN, and Si₃N₄, and the electrode pattern 120 may be formed as an electrode pattern for mounting the semiconductor chip 300 and an electrode pattern for mounting a driving element through brazing of an aluminum foil or a copper foil onto the ceramic base material 110.

The preparing of the conductive spacer 200 (S20) may prepare the conductive spacer 200 having a side surface formed as a curved surface through etching of the conductive spacer 200, and an area of the lower surface of the conductive spacer 200 may be formed to be larger than an area of the upper surface of the conductive spacer 200. As the etching, a wet etching process using photoresist may be performed. The wet etching process has an excellent selection ratio, and has an advantage of easily adjusting the etching speed by using the concentration and temperature of an etching solution.

In the preparing of the conductive spacer 200 (S20), the conductive spacer 200 may be formed of at least one of Cu, Mo, a CuMo alloy, and a CuW alloy. As an example, the conductive spacer 200 may be provided as a first conductive spacer 210 in the form of an “L” shape, and a second conductive spacer 220 of a block type.

The brazing (S30) may include disposing an edge of the conductive spacer 200 adjacent to an edge of the electrode pattern 120 of the ceramic substrate 100 The first conductive spacer 210 may be disposed adjacent to an “L”-shaped edge of the first electrode pattern 121. Further, the second conductive spacer 220 may be disposed adjacent to the edge of the second electrode pattern 122. In this case, the second conductive spacer 220 may be spaced apart from the first conductive spacer 210, and the side surface thereof may face the side surface of the first conductive spacer 210.

The brazing (S20) may include: disposing a brazing filler layer 400 having a thickness that is equal to or larger than 5 μm and equal to or smaller than 100 μm on an upper surface of the electrode pattern 120 by any one method of paste application, foil attachment, and P-filler; and brazing the brazing filler layer 400 through melting.

In the disposing of the brazing filler layer 400, the brazing filler layer 400 may be made of a material including at least one of Ag, Cu, AgCu, and AgCuTi.

The brazing of the brazing filler layer 400 by melting may be performed at a temperature that is equal to or higher than 450° C., and top weighting or pressurization may be carried out so that void does not occur.

The bonding of the electrodes 310 and 320 of the semiconductor chip 300 (S30) may bond the electrodes 310 and 320 of the semiconductor chip 300 onto the upper surface of the conductive spacer 200 by any one method of soldering and sintering. In order to braze all of the upper surface and the lower surface of the conductive spacer 200, it is required to perform the brazing process twice, and thus the flexure may occur on the ceramic substrate 100. Accordingly, it is preferable that the electrodes 310 and 320 of the semiconductor chip 300 are bonded onto the upper surface of the conductive spacer 200 is bonded onto the electrodes 310 and 320 of the semiconductor chip 300 by any one method of soldering and sintering.

The solder used for soldering may be composed of the solder paste of SnPb series, SnAg series, SnAgCu series, and Cu series having a high bonding strength and excellent high-temperature reliability. The silver paste has the excellent high-temperature reliability and high thermal conductivity in comparison to the solder. It is preferable that the silver paste includes 90 to 99 weight % of Ag powder and 1 to 10 weight % of binder so as to heighten the thermal conductivity. It is preferable that the Ag powder is composed of nanoparticles. The Ag powder of nanoparticles has a high bonding density and high thermal conductivity due to its large surface area.

As described above, according to the power module according to the present disclosure, it is possible to electrically connect the electrodes 310 and 320 of the semiconductor chip 300 to the electrode pattern 120 of the ceramic substrate 100 without a wire through the conductive spacer 200, and to adjust the height between the ceramic substrate 100 and the semiconductor chip 300 easily and variously to correspond to the molding mold, and thus the productivity can be improved. Further, since the heat generated from the semiconductor chip 300 is transferred to the ceramic substrate 100 through the conductive spacer 200, the heat dissipation efficiency can be heightened. In addition, since the lower surface of the conductive spacer 200 is brazed onto the electrode pattern 120 of the ceramic substrate 100 through the brazing filler layer 400, and the upper surface thereof is bonded onto the electrodes 310 and 320 of the semiconductor chip 300 through the bonding layer 500, the bonding strength is high, and the high-temperature reliability is excellent.

Although the present disclosure has been described with reference to the exemplified drawings, the present disclosure is not limited to the described embodiments, and it will be apparent to those of ordinary sill in the art to which the present disclosure pertains that various corrections and modifications are possible without departing from the spirit and scope of the present disclosure. Accordingly, it should be noted that such correction or modification examples belong to the scope of the present disclosure, and the scope of the present disclosure should be interpreted based on the appended claims.

1. A power module comprising:
a ceramic substrate on which an electrode pattern made of a metal is formed on at least one surface of a ceramic base material;
a conductive spacer having a lower surface that is bonded onto the electrode pattern of the ceramic substrate;
a semiconductor chip on which electrodes are bonded onto an upper surface of the conductive spacer; and
a brazing filler layer configured to braze the electrode pattern of the ceramic substrate and the lower surface of the conductive spacer.

2. The power module of claim 1, wherein an edge of the conductive spacer is disposed adjacent to an edge of the electrode pattern.

3. The power module of claim 1, wherein the conductive spacer comprises:
a first conductive spacer in the form of an “L” shape, and disposed adjacent to an edge of the “L” shape on the electrode pattern; and
a second conductive spacer disposed spaced apart from the first conductive spacer, and having a side surface facing a side surface of the first conductive spacer.

4. The power module of claim 1, wherein the conductive spacer has a side surface that is etched to form a curved surface, and an area of the lower surface of the conductive spacer is formed to be larger than an area of the upper surface of the conductive spacer.

5. The power module of claim 1, wherein the conductive spacer is formed of at least one of Cu, Mo, a CuMo alloy, and a CuW alloy.

6. The power module of claim 1, wherein the brazing filler layer is made of a material including at least one of Ag, Cu, AgCu, and AgCuTi.

7. The power module of claim 1, wherein the electrodes of the semiconductor chip are bonded onto the upper surface of the conductive spacer by a bonding layer including a solder or a silver paste (Ag paste).

8. A method for manufacturing a power module comprising:
preparing a ceramic substrate by forming an electrode pattern made of a metal on at least one surface of a ceramic base material;
preparing a conductive spacer;
brazing a lower surface of the conductive spacer onto the electrode pattern of the ceramic substrate; and
bonding electrodes of a semiconductor chip onto an upper surface of the conductive spacer.

9. The method of claim 8, wherein the preparing of the conductive spacer prepares the conductive spacer having a side surface formed as a curved surface through etching of the conductive spacer, and an area of the lower surface of the conductive spacer is formed to be larger than an area of the upper surface of the conductive spacer.

10. The method of claim 8, wherein in the preparing of the conductive spacer, the conductive spacer is formed of at least one of Cu, Mo, a CuMo alloy, and a CuW alloy.

11. The method of claim 8, wherein the brazing comprises disposing an edge of the conductive spacer adjacent to an edge of the electrode pattern.

12. The method of claim 8, wherein the brazing comprises:
disposing a brazing filler layer having a thickness that is equal to or larger than 5 μm and equal to or smaller than 100 μm on an upper surface of the electrode pattern by any one method of paste application, foil attachment, and P-filler; and
brazing the brazing filler layer through melting.

13. The method of claim 12, wherein in the disposing of the brazing filler layer, the brazing filler layer is made of a material including at least one of Ag, Cu, AgCu, and AgCuTi.

14. The method of claim 12, wherein the brazing is performed at a temperature that is equal to or higher than 450° C.

15. The method of claim 8, wherein the bonding of the electrodes of the semiconductor chip bonds the electrodes of the semiconductor chip onto the upper surface of the conductive spacer by any one method of soldering and sintering.
